(19) United States
(12) Patent Application Publication
(10) Pub. No.: US 2015/0243654 A1
(43) Pub. Date: Aug. 27, 2015

(54) SEMICONDUCTOR STRUCTURE AND METHOD FOR MANUFACTURING THE SAME

(71) Applicant: Institute of Microelectronics West Road, Chaoyang District, Beijing (CN)

(72) Inventors: Huicai Zhong, San Jose, CA (US); Qingqing Liang, Lagrangeville, NY (US); Chao Zhao, Kessel-lo (BE)

(73) Assignee: Institute of Microelectronics, Chinese Academy of Sciences, Beijing (CN)

(21) Appl. No.: 14/422,053

(22) PCT Filed: Sep. 17, 2012
(86) PCT No.: PCT/CN2012/081509

§ 371 Date: Feb. 17, 2015

(30) Foreign Application Priority Data
Aug. 28, 2012 (CN) 201210310953.9

(51) Int. Cl. H01L 27/088; H01L 29/40; H01L 21/265; H01L 29/06

(52) U.S. Cl. CPC H01L 27/088; H01L 29/0649; H01L 29/401; H01L 21/265

(57) ABSTRACT

The present invention provides a method for manufacturing a semiconductor structure, which comprises: a) forming gate lines extending along one direction on a substrate; b) forming a photoresist layer that covers the semiconductor structure; patterning the photoresist layer to form openings that span over the gate lines: c) implanting ions into the gate lines, such that the gate lines are insulated at the openings. The present invention enables the gate lines to maintain complete shape at formation of electrically isolated gates, which will not cause defects that exist in the prior art when forming a dielectric layers at subsequent steps, thereby guaranteeing performance of semiconductor devices. Additionally, the present invention further provides a semiconductor structure manufactured according to the method provided by the present invention.

The present application claims priority benefit of Chinese patent application No. 201210310953.9, filed on 28 Aug. 2012, entitled

“SEMICONDUCTOR STRUCTURE AND METHOD FOR MANUFACTURING THE SAME”, which is herein incorporated by reference in its entirety.

### FIELD OF THE INVENTION

The present invention relates to semiconductor manufacturing field, and particularly, to a semiconductor structure and a method for manufacturing the same.

### BACKGROUND OF THE INVENTION

With development of semiconductor structure manufacturing technology, integrated circuits with better performance and more powerful functions require greater element density, and sizes of elements and spacing among elements need to be further downscaled. Accordingly, lithography process faces greater demands and challenges during procedure of forming semiconductor structures.

Particularly, in manufacturing static random access memory (SRAM), line-and-cut dual patterning technology is usually applied in order to form gates inside semiconductor structures. Application of aforementioned technology is described here below with reference to FIG. 1 to FIG. 4.

FIG. 1 illustrates a part of a semiconductor structure with a gate formed according to the line-and-cut technology. As shown in FIG. 1, firstly, a photoresist layer 11 is overlaid on a substrate 10, on which a gate material layer has already been formed; the photoresist layer 11 is exposed and developed with a mask so as to make the photoresist layer 11 patterned for forming linear patterns of gate lines to be formed subsequently. Next, the gate layer is etched to form gate lines 12 (the structure shown in FIG. 1 is a structure in which the gate layer has already been etched). With reference to FIG. 2, which illustrates a cross-sectional view of the semiconductor structure along A-A direction as shown in FIG. 1; the gate lines 12 are arranged on the substrate 10, and the upper surface of the gate lines is overlaid with the photoresist layer 11. Next, as shown in FIG. 3, re-exposure is carried out by the cutting mask to form openings 13 on the photoresist layer 11, wherein the gate lines 12 are exposed via the openings 13. The gate lines 12 are etched via the openings 13 so that the gate lines 12 are cut off With reference to FIG. 4, the photoresist layer 11 is removed after the gate lines 12 are etched via the openings 13. At removal of the photoresist layer 11, a part of the gate lines 12 is removed to form cuts 16. Accordingly, the gate lines 12 are cut off into electrically isolated gates by the cuts 16, for example, electrically isolated gate 14 and gate 15 shown in FIG. 4.

However, aforementioned conventional process has the following advantages. Firstly, aforementioned process requires extremely precise distance between tips of gates in lithography. Specifically, it becomes increasingly difficult to implement such a gate line patterning process along with developments of downscaling size in devices. In particular, it becomes extremely difficult to manufacture cutting masks. Additionally, application of aforementioned technique would be more complicated in replacement gate and high K dielectric processes. Accordingly, sidewall spacer dual patterning is probably required at sub-22 nm technical node.

Meanwhile, spacers usually have to be formed on two sides of electrically isolated gates to surround the gates in subsequent processes. Since cuts 16 have been formed between gates, the spacer material is deposited on two sides of the gate and further into cutes 16 when forming the spacers. However, because the cuts 16 are quite narrow, spacer material is prone to form voids within the cuts, which consequently is unfavorable for subsequent processing. Particularly, short-circuits may arise at subsequent process for forming metal plugs. Additionally, if the gate is a dummy gate, the voids will give rise to short circuits at subsequent replacement gate process, which consequently deteriorates performance and stability of semiconductor devices.

### SUMMARY OF THE INVENTION

The present invention is intended to provide a semiconductor structure and a method for manufacturing the same to suppress defects arising at formation of gates for semiconductor structures, and is favorable for facilitating subsequent process for manufacturing semiconductor devices.

In one aspect, the present invention provides a method for manufacturing a semiconductor structure comprising:

(a) forming gate lines extending along one direction on a substrate;

(b) forming a photoresist layer to cover a semiconductor structure, and patterning the photoresist layer to form openings that span over the gate lines; and

(c) implanting ions into the gate lines via the openings, such that the gate lines are insulated at the openings.

Accordingly, the present invention further provides a semiconductor structure, which comprises:

a substrate;

gate lines, which extend along one direction and are formed on the substrate, and spacers formed on two sides of the gate lines; and

insulating regions, which isolate neighboring gate lines from each other at said direction, wherein the material for the insulating regions is different from the material for the spacers.

As compared to the line-and-cut dual patterning techniques in the prior art, the present invention provides a semiconductor structure and a method for manufacturing the same, in which an insulating layer is formed along gate length direction by ion implantation instead of forming cuts on gate lines, so as to form electrically isolated gates. Therefore, the gate lines are not disconnected physically, and the gate lines are kept in complete shape instead. Such processes would not cause defects that exist in the prior art, and therefore facilitates subsequent process and guarantees performance of semiconductor devices.

### BRIEF DESCRIPTION OF THE DRAWINGS

Other additional features, aspects and advantages of the present invention are made more evident after reading the following detailed description of exemplary embodiment(s) in conjunction with accompanying drawings:

FIG. 1 to FIG. 4 illustrate top views of structural diagrams of a semiconductor structure at each manufacturing stage according to a method for manufacturing a semiconductor structure in the prior art;

FIG. 5 illustrates a flow chart for an embodiment of a method for manufacturing a semiconductor structure provided by the present invention;

FIG. 6 to FIG. 22 illustrate structural diagrams of a semiconductor structure manufactured at each stages of the embodiment of the method for manufacturing a semiconductor structure, which is as illustrated in FIG. 5, provided by the present invention;

FIG. 23 to FIG. 25 illustrate structural diagrams of a semiconductor structure at stages of forming spacers and source/drain regions according to another embodiment of the present invention.

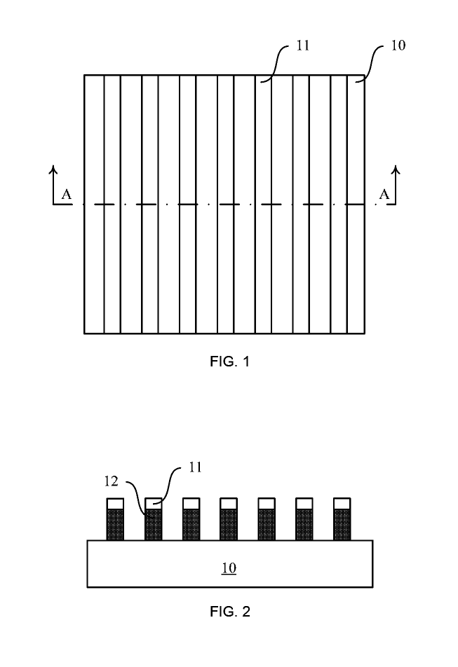

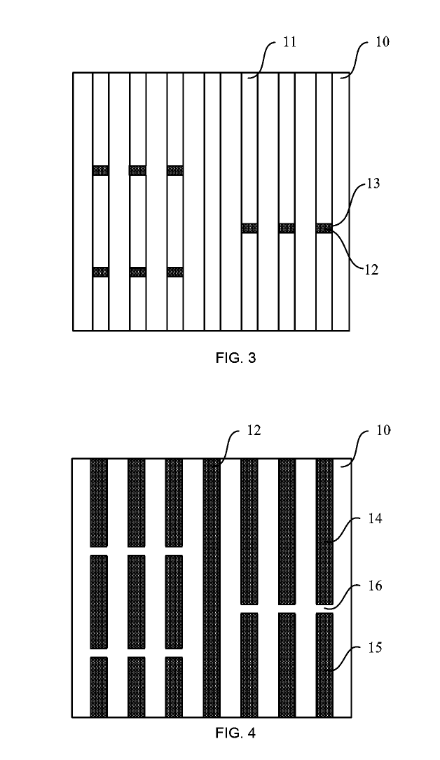

The same or similar reference signs in the appended drawings denote the same or similar elements.

### DETAILED DESCRIPTION OF THE INVENTION

The objectives, technical solutions and advantages of the present invention are made more evident according to the following detailed description of exemplary embodiments in conjunction with the accompanying drawings.

Embodiments of the present invention will be described in detail below, wherein examples of embodiments are illustrated in the appended drawings, in which same or similar reference signs throughout denote same or similar elements, or elements having same or similar functions. It should be understood that embodiments described below in conjunction with the drawings are illustrative. These embodiments are provided for explaining the present invention only, and thus shall not be interpreted as a limit to the present invention.

Various embodiments or examples are provided here below to implement different structures of the present invention. To simplify the disclosure of the present invention, descriptions of components and arrangements of specific examples are given below. Of course, they are only illustrative and not limiting the present invention. Moreover, in the present invention, reference numbers and/or letters may be repeated in different examples. Such repetition is for purposes of simplicity and clarity, and does not denote any relationship between respective embodiments and/or arrangements under discussion. Furthermore, the present invention provides various examples for various processes and materials. However, it is obvious for a person of ordinary skill in the art that other processes and/or materials may be alternatively utilized. In addition, following structures where a first feature is “on/above” a second feature may include an embodiment in which the first feature and the second feature are formed to be in direct contact with each other, and may also include an embodiment in which another feature is formed between the first feature and the second feature such that the first and second features might not be in direct contact with each other. However, layer structural diagrams are illustrated in the appended drawings. It should be noted that the appended drawings might not be drawn to scale. For purposes of clarity, some details are enlarged while some details are omitted from the appended drawings. Respective regions, shapes of layers and their relative dimensions and positional relationships are given exemplarily and thus are not drawn to scale, in which difference is allowed due to permitted manufacturing tolerance or technical limits in practice. Meanwhile, those skilled in the art can design regions/layers in different shapes, sizes and relative positions according to requirements in practice.

Preferred embodiments of the present invention are described according to a method for manufacturing a semiconductor structure provided by the present invention.

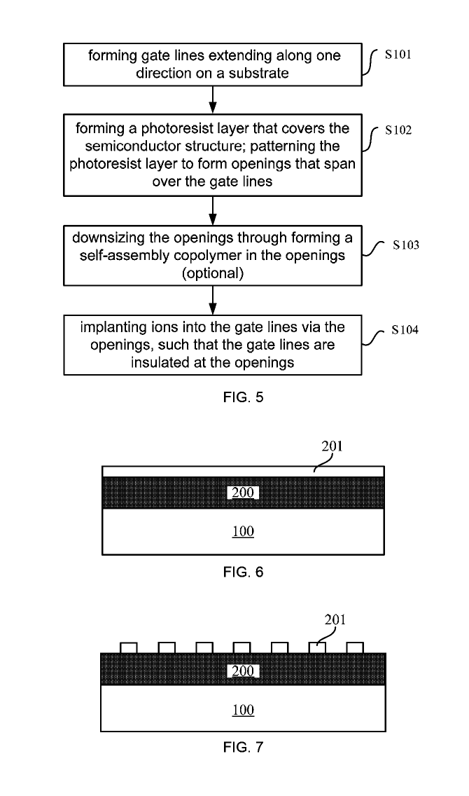

With reference to FIG. 5, which illustrates a flow chart of an embodiment of a method provided by the present invention, the method comprises the following steps.

In step S101, gate lines extending along one direction are formed on a substrate.

In step S102, a photoresist layer is formed to cover a semiconductor structure. The photoresist layer is patterned to form openings that span over the gate lines.

At an optional step S103, a self-assembly copolymer is formed within openings to narrow the openings.

In step S104, ions are implanted into the gate lines via the openings, such that the gate lines are insulated at the openings.

With reference to FIG. 6 to FIG. 9, the step S101 is performed to form gate lines 210 along one direction on a substrate 100. FIG. 6 to FIG. 9 illustrate respectively structural diagrams of a semiconductor structure viewed from different directions when forming the gate lines 210 according to a method for manufacturing a semiconductor structure provided by the present invention. Firstly, as shown in FIG. 6, a gate stack layer 200 and a photoresist layer 201 are formed on the substrate 100. The substrate 100 comprises Si substrate (e.g. Si wafer). According to design requirements in the prior art (e.g. a P-type substrate or an N-type substrate), the substrate 100 may be of various doping configurations. The substrate 100 in other embodiments may further comprise other basic semiconductors, for example germanium. Alternatively, the substrate 100 may comprise a compound semiconductor, such as SiC, GaAs, InAs or InP.

Typically, the substrate 100 may have, but not limited to, a thickness of around several hundred micrometers, which, for example, may be in the range of 400 μm-800 μm. According to design requirements, the substrate 100 may be bulk Si or Silicon-On-Insulator (SOI). A shallow trench isolation (STI) structure may be formed on the substrate in advance, such that the STI structure separates the surface of the substrate into independent active regions.

The material for the photoresist layer 201 may be a vinyl monomer material, a material containing nitrine quinone compound or a polyethylene lauric acid material. Of course, other materials as appropriate may be used according to manufacturing requirements in practice.

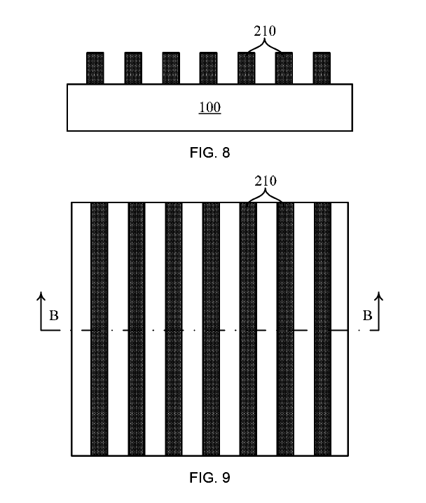

The gate lines 210 extending along one direction (the direction perpendicular to paper sheet shown in FIG. 8) are formed by patterning and etching photoresist on the gate stack layer 200. Firstly, the photoresist layer 201 is exposed and developed with a mask to expose the gate stack layer 200 so as to obtain linear patterns corresponding to patterns of gate lines 210 to be formed subsequently, as shown in FIG. 7. Next, the gate stack layer 200 is further etched to form gate lines 210, and then the photoresist layer 201 is removed, as shown in FIG. 8. Since the gate lines 210 are formed by the gate stack, which comprises a gate dielectric layer and a gate material layer on the gate dielectric layer, the gate dielectric layer is located in the lower portion of the gate stack near to the substrate 100. Usually, the material for the gate dielectric layer may be a thermal oxide layer, which comprises SiO₂ or SiOₓN_{y}, or may be a high K dielectric, for example, any one selected from a group consisting of HfO₂, HfSiO, HfSiON, HfTaO, HfTiO, HfZrO, Al₂O₃, La₂O₃, ZrO₂, LaAlO or combinations thereof, with a thickness in the range of 1 nm˜4 nm. The gate material layer may be any one selected from a group consisting of Poly-Si, Ti, Co, Ni, Al, W, alloy, metal silicide or combinations thereof. In some embodiments, the gate material layer may be in a multi-layer structure, which, for example, is formed by a gate metal layer and a gate electrode layer. The material for the gate metal layer may be any one selected from a group consisting of TaC, TiN, TaTbN, TaErN, TaYbN, TaSiN, HfSiN, MoSiN, RuTaₓ, NiTa or combinations thereof, with a thickness in the range of 5 nm-20 nm. Poly-Si may be selected as the material for the gate electrode layer 203, and may have a thickness in the range of 20 nm-80 nm. Optionally, the gate stack may further comprise at least one dielectric cap layer that covers the gate material layer for protecting other structures of the gate stack located beneath it. With reference to FIG. 9, the structural diagram of a semiconductor structure shown in FIG. 8 is a cross-sectional structural view along B-B direction of the top view of a semiconductor structure shown in FIG. 9. As shown in FIG. 9, the gate lines 210 extend along the direction parallel to the paper length direction and are arranged parallel to each other with equal pitches. In other embodiments, the size of gate lines, extending direction and pitches between gate lines may be determined according to requirements for designing semiconductor devices.

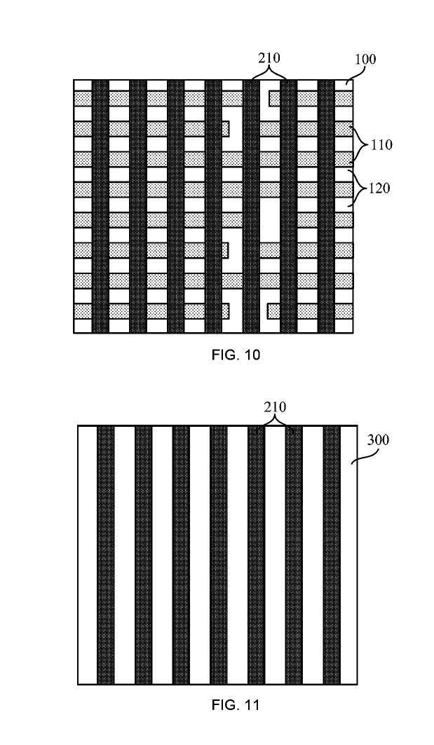

With reference to FIG. 10, after the gate lines 210 are formed by patterning the gate stack layer 200, the active regions 110 and shallow trench isolation structures 120 beneath are exposed. Optionally, source/drain regions may be formed in the active regions 110. Formation of source/drain regions may comprise steps of forming firstly source/drain extension regions on two sides of the gate lines, and then forming spacers on sidewalls of the gate lines, and finally forming source/drain regions on two sides of the spacers. Processes for forming source/drain extension regions, spacers and source/drain regions are widely known in the art, and are omitted here.

In the present embodiment, neither source/drain regions nor spacers are formed at this stage, and following description is based on such a structure.

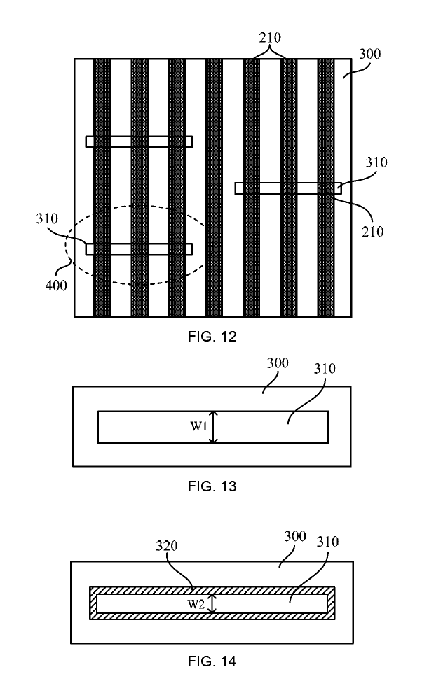

With reference to FIG. 11 and FIG. 12, the step S102 is performed to form a photoresist layer 300 that covers the semiconductor structure. Then the photoresist layer 300 is patterned to form openings 310 that span over the gate lines.

Usually, the material for the photoresist layer 300 may be a vinyl monomer material, a material containing nitrine quinone compound or a polyethylene lauric acid material. As shown in FIG. 11, the photoresist layer 300 is formed on the entire semiconductor structure, namely, covering the gate lines 210 and substrate 100 on two sides thereof However, it should be understood that aforementioned term “cover” should be interpreted as follows: in some embodiments, the photoresist layer 300 directly covers the gate lines 210 and the substrate 100 on two sides thereof; and in other embodiments, since another structure such as a strained layer has already been formed to cover the gate lines 210 and the substrate 100 on two sides thereof with regard to manufacturing requirements, therefore, the photoresist layer 300 covers the strained layer directly. Accordingly, there may be some other structures presented between the photoresist layer 300 and the gate lines 210 and the substrate 100. In this case, it is possible to apply the photoresist layer 300 on the gate lines 210 and the substrate 100 only for purposes of patterning.

With reference to FIG. 12, the openings 310 that span over the gate lines are formed on the photoresist layer 300. In an embodiment where the photoresist layer 300 covers the gate lines directly, the gate lines 210 are exposed in the openings 310. In the present embodiment, a plurality of gate lines 210 are exposed in the openings 310 shown in FIG. 12, such that the positions where the gate lines 210 are cut off are configured in line. In other embodiments, only one gate line 210 may be exposed in the openings 310. The position of the openings 310 shown in FIG. 12 is only exemplary. Preferably, when a shallow trench isolation structure 120 is formed on the substrate 100, the openings 310 are usually formed above the shallow trench isolation structure 120. Therefore, the layout like this is advantageous for saving area and enhancing integrity. Additionally, the distance between two opposite walls of the opening 310 is made less than 50 nm along the gate width direction, which is also advantageous for saving area and enhancing integrity.

In this case, the step S103 is optionally performed to form a self-assembly copolymer within the openings to narrow the openings.

Because the openings 310 are further processed in subsequent steps, FIG. 13 is to be referred in order to describe the technical solution of the present invention more explicitly. FIG. 13 illustrates a locally enlarged view of an opening 310 inside the region 400 shown in FIG. 12, wherein W1 represents the distance between two opposite walls of the opening along the gate width direction. During process of lithography, the size of openings 310 may be subject to limit from technical difficulties, and thus W1 may be in a range of, for example, 30 nm≦W1≦50 nm.

With reference to FIG. 14, which illustrates a structural diagram after formation of an additional layer 320 onto inner walls of the openings 310 as shown in FIG. 13. As mentioned above, the material for the photoresist layer 300 may be preferably photoresist, and accordingly, the material for the inner walls of the openings 310 is also photoresist. It is possible to grow a self-assembly copolymer material on the inner walls of the openings 310, while the grown self-assembly copolymer forms the additional layer 320. Namely, the additional layer 320 is the self-assembly copolymer layer 320. Description of growing a self-assembly copolymer material on a photoresist layer may be referred to “Self-Assembling Materials for Lithographic Patterning: Overview, Status and Moving Forward”, which was published on Alternative Lithographic Technologies II, issue 7637, the International Society for Optical Engineering (SPIE). The method for growing self-assembly copolymer material on a photoresist is described in the aforementioned reference. Self-assembly copolymer can grow on any area of exposed photoresist due to its characteristics. For purposes of simplicity and explicitness, FIG. 14 merely illustrates the self-assembly copolymer grown on such a critical position as the inner walls of the opening 310, so as to show its position in the opening 310.

After formation of the self-assembly copolymer layer 320 on the inner walls of the openings 310, the distance between two opposite walls of the opening 310 along the gate width direction becomes W2, wherein W2<W1, because the self-assembly copolymer 320 has a thickness. Usually, W2 is less than 30 nm, for example, 10 nm. Therefore, after the self-assembly copolymer layer 320 is laid on the inner walls of the openings 310, the distance between two opposite walls of the opening 310 along the gate width direction is further decreased.

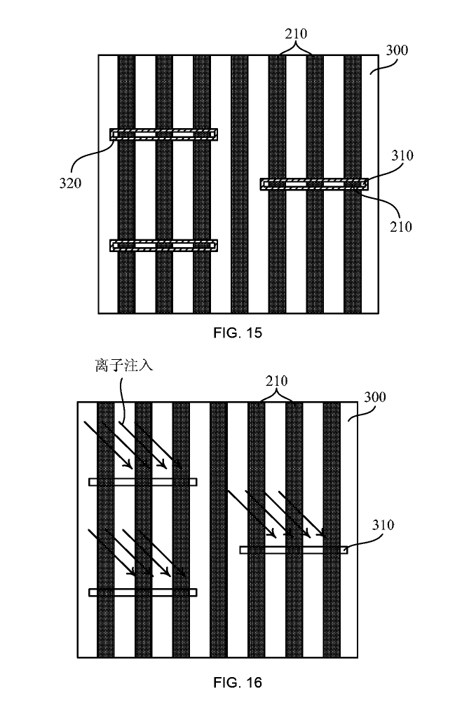

With reference to FIG. 15, inner walls of openings 310 are covered by the self-assembly copolymer 320, and therefore, the area of the exposed gate lines 210 becomes smaller than that before formation of the self-assembly copolymer 320. Formation of an additional layer on inner walls of the openings on the photoresist layer decreases the distance between two opposite walls of the opening along the gate width direction, namely, the distance between ends of electrically isolated neighboring gates that are positioned along the same line, which therefore saves area and enhances integrity of semiconductor devices.

The step S103 might not be performed in the present embodiment, and the following description is given on such a basis.

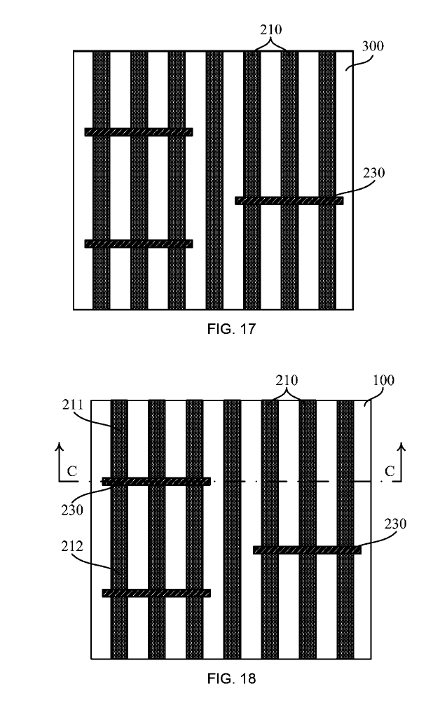

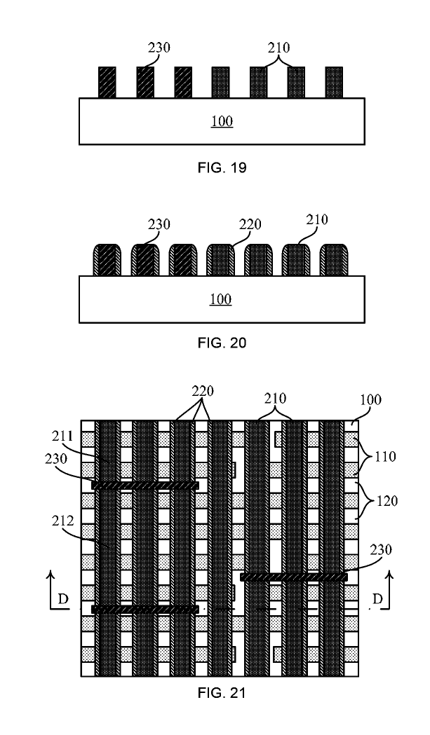

Next, with reference to FIG. 16 to FIG. 19, the step S104 is performed. Ions are implanted into the gate lines 210 via the openings 310, such that the gate lines 210 become insulated at the openings. Ions are implanted via the openings 310, such that the exposed gate lines 210 react to form an insulating layer 230, which cuts off the gate lines 210 along gate length direction such that the gate lines 210 forms electrically isolated gates. Firstly, with reference to FIG. 16, ions are implanted via the openings 310, wherein ions to be implanted are usually oxygen ions, since oxygen ion implantation enables the exposed gate lines to be oxidized, and the oxide resulted from oxidizing the gate lines 210 is an insulating material. With reference to FIG. 17, the insulating layer 230 is formed after ion implantation. Take oxygen ion implantation as an example. The insulating layer 230 is composed of oxides resulted from reaction of exposed gate lines 210 with oxygen ions, such as SiO₂, metal oxide or the like (which depends on the material of the gate stack). With reference to FIG. 18, the photoresist layer 300 may be removed after the insulating layer 230 has been formed for purposes of facilitating subsequent processes. The insulating layer 230 cuts off the gate lines 210 along the gate length direction, such that the gate lines 210 forms electrically isolated gates, such as electrically isolated gate 211 and gate 212 shown in FIG. 18. However, it should be noted that the openings 310 in the present embodiment expose no only a plurality of gate lines 210 but also partially expose the substrate 100. However, since openings are usually located above the shallow trench isolation structure, the active regions would not be oxidized by implanted oxygen ions. FIG. 19 is now referenced in order to further described the position for forming the insulating layer 230. FIG. 19 illustrates a cross-sectional structural view of a semiconductor structure along C-C direction shown in FIG. 18. According to characteristic of oxygen ion implantation, energy of oxygen ions is controlled by electric field, such that the gate lines 210 are oxidized thoroughly from surface to center to form the insulating layer 230. As shown in FIG. 19, the insulating layers 230 is located on cross-sections of the gate lines 210 and electrically separates the entire gate line 210 into two parts. Namely, the gate lines 210, which is conductive before, now become open-circuit because the exposed portions thereof have been oxidized by oxygen ions. But the whole gate lines 210 are still complete in shape. There is no need to damage the physical shape of gate lines or to form any physical cuts, which is different from the prior art.

After formation of the insulating layer 230, the semiconductor structure may be further processed, as shown in FIG. 20. Spacers 220 are formed on two sides of the gate lines 210; the sidewalls spacers 220 may be formed with Si₃N₄, SiO₂, SiOₓN_{y}, SiC and/or other materials as appropriate. The spacers 220 may be in a multi-layer structure. The spacers 220 may be formed by depositing-etching process, with a thickness in the range of about 10 nm-100 nm. FIG. 20 illustrates a cross-sectional structural diagram of the semiconductor structure along D-D direction shown in FIG. 21. With reference to FIG. 21, the spacers 220 are formed on two sides of the gate lines 210, i.e., on two sides of gate 211 or gate 212, for purposes of protecting the gates. Source/drain extension regions may be formed on two sides of gates before the spacers are formed. Then, after formation of spacers, source/drain regions may be formed outside the spacers, which are not described here in order not to obscure.

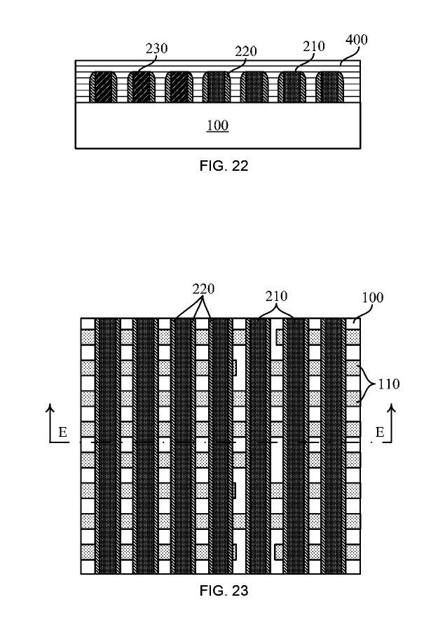

Additionally, according to design requirements of semiconductor structures, at least one strained layer 400 may be formed to cover the gate lines 210, the spacers 220 and the substrate 100 after formation of spacers 220. The strained layer is provided for purposes of increasing stress so as to enhance performance of semiconductor devices, as shown in FIG. 22.

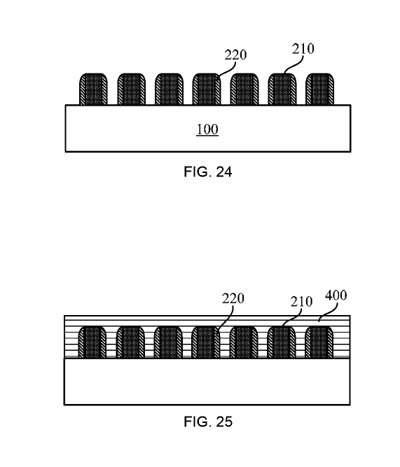

Optionally, it is possible to firstly form spacers 220 and at least one strained layer 400, and then form the insulating layer 230. Namely, the step for forming the insulating layer 230 may be performed at last. With reference to the above embodiments, a pattern composed of gate lines 210 shown in FIG. 10 is formed. Next, the semiconductor structure shown in FIG. 23 is formed. Namely, source/drain extension regions, spacers 220 and source/drain regions on two sides of the gate lines 210 are formed. FIG. 24 illustrates a cross-sectional diagram of the semiconductor structure along E-E direction as shown in FIG. 23. Then, at least one strained layer 400 that covers gate lines 210, spacers 220 and the substrate 100 may be formed, as shown in FIG. 25. Then, step for forming the insulating layer 230 is performed. In the present embodiment, the processes for forming the spacers 220 and forming the strained layer 400 may be referred to related parts of the above embodiments, and the process for forming the insulating layer 230 may also be referred to the above embodiments. However, it should be noted that because gate lines 210 are covered by the strained layer 400 in the present embodiment, the openings 310 formed on the photoresist layer 300 expose the strained layer 400 on the gate lines 210 in some embodiments. Accordingly, energy and dose of oxygen ions to be implanted should be adjusted so as to enable oxygen ions to penetrate the strained layer 400 and thoroughly oxidize the gate lines 210 under the strained layer 400.

With regard to the technical solution of the present invention, the step for forming the insulating layer 230 may be performed after the step for forming the spacers 220, or after both steps for forming the spacers 220 and forming the strained layer 400 (usually, the strained layer 400 is formed after formation of the spacers 220), or may be performed before formation of spacers 220 and the strained layer 400. Therefore, it is possible to arrange manufacturing steps flexibly, and a variety of manufacturing procedures may be provided. Nonetheless, it is noteworthy that the step for forming the insulating layer 230 (i.e. forming electrically isolated gates) should precede the step for forming contact plugs that are in contact with source/drain regions.

No matter which method for manufacturing a semiconductor structure provided by the present invention is performed, the step for forming the insulating layer 230 may be followed by such steps as: forming at least one dielectric layer that covers the gate lines, spacers and source/drain regions (if a strained layer 400 has already been formed in the semiconductor structure, then the at least one dielectric layer also covers the strained layer 400), and forming contact plugs, which are embedded within the at least one dielectric layer, to be electrically connected with source/drain regions 100 and/or the gates. The at least one dielectric layer may be formed on the substrate 100 by means of Chemical-Vapor Deposition (CVD), High-Density Plasma CVD or other processes as appropriate. The material for the dielectric layer may be any one selected from a group consisting of SiO₂, carbon-doped SiO₂, BPSG, PSG, USG, SiOₓN_{y}, a low k material or combinations thereof. The material for the contact plugs may be any one selected from a group consisting of W, Al, TiAl alloy or combinations thereof.

As compared to the line-and-cut dual patterning techniques in the prior art, the present invention provides a semiconductor structure and a method for manufacturing the same in which an insulating layer is formed along gate length direction by ion implantation instead of forming cuts on gate lines, so as to form electrically isolated gates. This process neither causes damage to the physical shape of the gate lines 210 nor forms any physical cuts. Instead, the gate lines 210 maintain its complete shape. Such processes would not give rise to defects in the prior art when forming a dielectric layer at subsequent steps, and therefore facilitates subsequent process and guarantees performance of semiconductor devices. In addition, formation of the insulating layer 230 is not limited by formation of spacers 220 and the strained layer 400. Therefore, manufacturing steps are flexible and a variety of manufacturing procedures may be provided, which can satisfy more scenarios in practice.

A preferred structure of the semiconductor structure provided by the present invention is described here below. Now refer to FIG. 20 and FIG. 21, wherein FIG. 21 illustrates a top view of an embodiment for a semiconductor structure of the present invention. In the preferred embodiment, the semiconductor structure comprises:

a substrate 100;

gate lines 210 extending along one direction, which are formed on the substrate; and spacers 220 formed on two sides of the gate lines;

insulating regions 230, which isolate the neighboring gate lines 210 along said direction, wherein the material for the insulating regions 230 is different from the material for the spacers 220.

The substrate 100 comprises Si substrate (e.g. Si wafer). According to design requirements in the prior art (e.g. a P-type substrate or an N-type substrate), the substrate 100 may be of various doping configurations. The substrate 100 in other embodiments may further comprise other basic semiconductors, for example, germanium. Alternatively, the substrate 100 may comprise a compound semiconductor, such as SiC, GaAs, InAs or InP. Typically, the substrate 100 may have, but is not limited to, a thickness of around several hundred micrometers, which, for example, may be in the range of 400 μm-800 μm. There may be a shallow trench isolation structure 120 formed on the substrate 100. The shallow trench isolation structure 120 separates the surface of the substrate 100 into independent active regions 110.

The gate line 210 is a gate stack, which comprises a gate dielectric layer and a gate material layer on the gate dielectric layer, and therefore, the gate dielectric layer is located in the lower position in the gate stack on the substrate 100. Usually, the material for the gate dielectric layer may be a thermal oxide layer, which comprises SiO₂ or SiOₓN_{y}, or may be a high K dielectric, for example, any one selected from a group consisting of HfO₂, HfSiO, HfSiON, HfTaO, HfTiO, HfZrO, Al₂O₃, La₂O₃, ZrO₂, LaAlO or combinations thereof, with a thickness in the range of 1 nm-4 nm. The gate material layer may be any one selected from a group consisting of Poly-Si, Ti, Co, Ni, Al, W, alloy, metal silicide or combinations thereof. In some embodiments, the gate material layer my be in a multi-layer structure, which, for example, is formed by a gate metal layer and a gate electrode layer. The material for the gate metal layer may be any one selected from a group consisting of TaC, TiN, TaTbN, TaErN, TaYbN, TaSiN, HfSiN, MoSiN, RuTaₓ, NiTa or combinations thereof, with a thickness in the range of 5 nm-20 nm. Poly-Si may be selected as the material for the gate electrode layer, whose thickness may be in the range of 20 nm-80 nm. Optionally, the gate stack may further comprise at least one dielectric cap layer that covers the gate material layer for purposes of protecting other structures of the gate stack located beneath it. Usually, the size of gate lines and the pitch between gate lines may be determined according to requirements for designing semiconductor devices. Generally, the gate lines are arranged in parallel.

In addition, spacers 220 are formed on two sides of the gate lines and surround the gate lines. The spacers 220 may be formed with Si₃N₄, SiO₂, SiOₓN_{y}, SiC and/or other material as appropriate. The spacers 220 may be in a multi-layer structure. The spacers 220 may be formed by depositing-etching process, with a thickness in the range of about 10 nm-100 nm. Source/drain regions may be formed within active regions 110 on the substrate 100. Generally, source/drain regions are formed after formation of gate lines 210.

The gate lines 210 are cut off by the insulating layer 230 along the gate length direction, such that the gate lines 210 are cut into electrically isolated gates, such as gate 211 and gate 212. The gate 211 and the gate 212 are positioned on one gate line 210 but are electrically isolated by the insulating layer 230. Usually, the material for the insulating layer 230 is an insulating material such as an oxide of the material for forming the gate stack (i.e. material for the gate lines), for example, SiO₂ and metal oxide, which is different from the material for the spacers 220. The above mentioned process is different from isolating tips of neighboring gates by means of spacer material in the prior art. Preferably, the insulating layer 230 is formed above the shallow trench isolation structure 120, which is favorable for saving area and improving integrity. In the gate width direction, the thickness of the insulating layer 230 is less than 50 nm, for example 10 nm.

The insulating layer 230 is formed by means of ion implantation, for example, implanting oxygen ions.

Now refer to FIG. 20 in order to further describe the structure of the insulating layer. FIG. 20 illustrates a cross-sectional structural diagram of the semiconductor structure along D-D direction as shown in FIG. 21. As shown in the drawing, the gate lines 210 are electrically isolated after being cut off by the insulating layer 230.

Optionally, as shown in FIG. 22, the semiconductor structure further comprises at least one strained layer 400, which covers the gate lines 210, the spacers 200 and source/drain regions, for purpose of providing a stress so as to enhance performance of semiconductor devices.

Optionally, the semiconductor structure further comprises at least a dielectric layer that covers the gate lines, spacers and source/drain regions (if a strained layer 400 has already been formed in the semiconductor structure, the at least one dielectric layer covers the strained layer 400); contact plugs, which are embedded within the at least one dielectric layer, are electrically connected to source/drain regions and/or the gates. The material for the at least one dielectric layer may be any one selected from a group consisting of SiO₂, carbon-doped SiO₂, BPSG, PSG, USG, SiOₓN_{y}, a low k material or combinations thereof. The material for the contact plugs may be any one selected from a group consisting of W, Al, TiAl alloy or combinations thereof.

It should be noted that the semiconductor structure provided in the embodiments and other semiconductor structures may be included in one semiconductor device.

Although the exemplary embodiments and their advantages have been described in detail herein, it should be understood that various alternations, substitutions and modifications may be made to the embodiments without departing from the spirit of the present invention and the scope as defined by the appended claims. As for other examples, it may be easily understood by a person of ordinary skill in the art that the order of the process steps may be changed without departing from the scope of the present invention.

In addition, the scope, to which the present invention is applied, is not limited to the process, mechanism, manufacture, material composition, means, methods and steps described in the specific embodiments in the specification. According to the disclosure of the present invention, a person of ordinary skill in the art should readily appreciate from the disclosure of the present invention that the process, mechanism, manufacture, material composition, means, methods and steps currently existing or to be developed in future, which perform substantially the same functions or achieve substantially the same as that in the corresponding embodiments described in the present invention, may be applied according to the present invention. Therefore, it is intended that the scope of the appended claims of the present invention includes these process, mechanism, manufacture, material composition, means, methods or steps.

What is claimed is:

1. A method for manufacturing a semiconductor structure, comprising:
a) forming gate lines extending along one direction on a substrate;
b) forming a photoresist layer that covers the semiconductor structure, and patterning the photoresist layer to form openings that span over the gate lines; and
c) implanting ions into the gate lines via the openings such that the gate lines are insulated at the openings.

2. The method of claim 1, wherein the step a) further comprises forming spacers on two sides of the gate lines.

3. The method of claim 1, wherein prior to performing the step c), the method further comprises narrowing the openings by forming a self-assembly copolymer in the openings.

4. The method of claim 1, wherein:
the ion implantation is oxygen ion implantation.

5. The method of claim 1, wherein:
the openings are located above a shallow trench isolation in the substrate.

6. The method of claim 1, wherein prior to performing the step b), the method further comprises:
d) forming spacers on two sides of the gate lines.

7. The method of claim 2, wherein prior to performing the step b) and after performing the step a), the method further comprises:
e) forming at least one strained layer that covers the gate lines and spacers.

8. A semiconductor structure, comprising:
a substrate;
gate lines extending along one direction and formed on the substrate, and spacers formed on two sides of the gate lines; and
insulating regions, which isolate neighboring gate lines from each other along said direction, wherein the material for the insulating regions is different from the material for the spacers.

9. The semiconductor structure of claim 8, wherein:
the material for the insulating regions is oxide.

10. The semiconductor structure of claim 8, wherein:
the insulating regions are formed above the shallow trench isolation structure.

11. The semiconductor structure of claim 8, wherein:
The thickness of the insulating regions at said direction is less than 20 nm.
